(19) United States
(12) Patent Application Publication
(10) Pub. No.: US 2026/0026342 A1
(43) Pub. Date: Jan. 22, 2026

(54) MODULE INCLUDING SOLID-STATE DRIVE, MULTI-CHIP MODULE, AND HEAT DISSIPATION METHOD

(71) Applicant: MACRONIX INTERNATIONAL CO., LTD., Hsinchu (TW)

(72) Inventors: Chun-Hung LAI, Hsinchu County (TW); Chun-Lien SU, Taichung City (TW); Ming-Te YEH, Hsinchu County (TW); Jyun-Lin HUANG, Kaohsiung City (TW)

(21) Appl. No.: 18/779,466

(22) Filed: Jul. 22, 2024

(51) Int. Cl. H01L 23/367; H10B 80/00

(52) U.S. Cl. CPC H01L 23/367; H10B 80/00

(57) ABSTRACT

A module including a solid-state drive is provided. The module includes a substrate having an upper surface, a control unit on the upper surface of the substrate and having a first critical operation temperature, a first storage unit on the upper surface of the substrate and having a second critical operation temperature, a first thermal conductive element on the control unit, wherein the control unit is between the first thermal conductive element and the substrate, and a second thermal conductive element on the first storage unit, wherein the first storage unit is between the second thermal conductive element and the substrate. The first critical operation temperature is greater than the second critical operation temperature. There is no direct thermal coupling between the first thermal conductive element and the second thermal conductive element.

### BACKGROUND

### Technical Field

The disclosure relates to a module including electronic components and a heat dissipation method, and more particularly to a module including electronic components and a thermal conductive element and a heat dissipation method.

### Description of the Related Art

Modules including electronic components often generate heat during operation. Heat may cause damage to electronic components and affect the performance and service life of the module. Therefore, there is still a need to provide an improved module and heat dissipation method.

### SUMMARY

According to an embodiment of the present disclosure, a module including a solid-state drive is provided. The module including a solid-state drive includes a substrate having an upper surface, a control unit on the upper surface of the substrate and having a first critical operation temperature, a first storage unit on the upper surface of the substrate and having a second critical operation temperature, a first thermal conductive element on the control unit, and a second thermal conductive element on the first storage unit. The first critical operation temperature is greater than the second critical operation temperature. The control unit is between the first thermal conductive element and the substrate. The first storage unit is between the second thermal conductive element and the substrate. There is no direct thermal coupling between the first thermal conductive element and the second thermal conductive element.

According to an embodiment of the present disclosure, a multi-chip module is provided. The multi-chip module includes a substrate having an upper surface, a first chip on the upper surface of the substrate and having a first critical operation temperature, a second chip on the upper surface of the substrate and having a second critical operation temperature, a first thermal conductive element on the first chip, and a second thermal conductive element on the second chip. The first critical operation temperature is greater than the second critical operation temperature. The first chip is between the first thermal conductive element and the substrate. The second chip is between the second thermal conductive element and the substrate. The first thermal conductive element is separated from the second thermal conductive element. The first chip has a first operation temperature and the second chip has a second operation temperature when the multi-chip module is in operation. In response to the first operation temperature being equal to or greater than the first critical operation temperature or the second operation temperature being equal to or greater than the second critical operation temperature, the first chip reduces the operation speed of the multi-chip module.

According to an embodiment of the present disclosure, a heat dissipation method is provided. The heat dissipation method is adapted to a multi-chip module. The multi-chip module includes a control unit having a first critical operation temperature, a first storage unit having a second critical operation temperature less than the first critical operation temperature, a first thermal conductive element, a second thermal conductive element and a thermal conductive layer. The first critical operation temperature is greater than the second critical operation temperature. The heat dissipation method includes: transferring heat in the control unit to the first thermal conductive element; transferring heat in the first storage unit to the second thermal conductive element; transferring the heat from the first thermal conductive element to the thermal conductive layer; transferring the heat from the second thermal conductive element to the thermal conductive layer; blocking the first thermal conductive element from directly thermally coupling with the second thermal conductive element, wherein the control unit and the first storage unit have different heat conduction paths.

The above and other embodiments of the disclosure will become better understood with regard to the following detailed description of the non-limiting embodiment(s). The following description is made with reference to the accompanying drawings.

### BRIEF DESCRIPTION OF THE DRAWINGS

FIG. 1 illustrates a schematic view of a module according to an embodiment of the present disclosure.

FIG. 2 illustrates a schematic view of a module according to an embodiment of the present disclosure.

FIG. 3 illustrates a schematic view of a module according to an embodiment of the present disclosure.

FIG. 4 illustrates a schematic view of a module according to an embodiment of the present disclosure.

FIG. 5 illustrates a schematic view of a module according to an embodiment of the present disclosure.

FIG. 6 illustrates a schematic view of a module according to an embodiment of the present disclosure.

FIG. 7 illustrates a schematic view of a module according to an embodiment of the present disclosure.

FIG. 8 illustrates a schematic view of a module according to an embodiment of the present disclosure.

FIG. 9 illustrates a schematic view of a module according to an embodiment of the present disclosure.

### DETAILED DESCRIPTION

Various embodiments will be described more fully hereinafter with reference to accompanying drawings, which are provided for illustrative and explaining purposes rather than a limiting purpose. For clarity, the components may not be drawn to scale. In addition, some components and/or reference numerals may be omitted from some drawings. It is contemplated that the elements and features of one embodiment can be beneficially incorporated in another embodiment without further recitation. The illustration uses the same/similar reference numerals to indicate the same/similar elements. As used in the specification and the appended claims, term “and/or” includes any and all combinations of one or more of the associated listed items.

The embodiments according to the present disclosure can be applied to many different types of modules including electronic components. For example, the embodiments can be applied to, but not limited to, multi-chip modules including chips. The chips in the multi-chip module can have any functions. For example, the chips in the multi-chip module can be control unit, a storage unit such as single-level cell (SLC), 2-level cell, triple-level cell and quad-level cell (QLC), an input/output unit, a communication unit, etc.

Referring to FIG. 1, FIG. 1 illustrates a schematic view of a module 10 according to an embodiment of the present disclosure. The module 10 includes a substrate 101, one or more first chips 111, one or more second chips 112 and a heat dissipation device 190. The substrate 101 can be a printed circuit board (PCB) with conductive traces. The substrate 101 has an upper surface 101U. One or more first chips 111 and one or more second chips 112 are disposed on the upper surface 101U of the substrate 101 and separated from each other. The first chip 111 has a first critical operation temperature. The second chips 112 has a second critical operation temperature. The first critical operation temperature of the first chip 111 is greater than the second critical operation temperature of the second chip 112. The term “critical operation temperature” throughout the present specification can be defined as, when the temperature of the element is greater than or equal to this temperature, the operation performance of the element will decrease to prevent the element from overheating. Different elements can have different critical operation temperatures. The first chip 111 and the second chip 112 can have any functions. For example, the first chip 111 and the second chip 112 can be control units, storage units, etc. In an embodiment, the first chip 111 is a control unit for a storage device, the second chip 112 is a storage unit for the storage device, the storage unit may have memory cells, and the first chip 112 can communicate with the second chips 112 to operate the second chip 112. For example, the first chip 112 can communicate with the second chips 112 to perform a reading, programming or erasing operation. In an embodiment, the first chop 111 is a control unit of a solid-state drive (SSD) and the second chip 112 is a non-volatile storage unit or a volatile storage unit of a solid-state drive. The non-volatile storage unit of a solid-state drive may include NAND flash memory, NOR flash memory, etc. The volatile storage unit of a solid-state drive may include dynamic random-access memory (DRAM), static random-access memory (SRAM), etc. In an embodiment, each first critical operation temperature of one or more first chips 111 is greater than 100° C., and each second critical operation temperature of one or more second chips 112 is less than 100° C. or less than 90° C.

FIG. 1 shows one first chip 111 and two second chip 112, but the present disclosure is not limited thereto; the module 10 can include different numbers of first chips 111 and different numbers of second chips 112. In embodiment in which the module 10 includes multiple first chips 111 and/or multiple second chips 112, the first chips 111 may have the same function or different functions, the second chips 112 may have the same function or different functions, the first chips 111 may have the same first critical operation temperature or different first critical operation temperatures, and the second chips 112 may have the same second critical operation temperature or different second critical operation temperatures, but all of the second critical operation temperatures of the second chips 112 are less than all of the first critical operation temperature of the first chips 111.

The heat dissipation device 190 is disposed on one or more first chips 111 and one or more second chips 112. The heat dissipation device 190 includes a first adhesion layer 121, a second adhesion layer 122, a first thermal conductive element 131, a second thermal conductive element 132 and a thermal conductive layer 141. The first thermal conductive element 131 is disposed on the first chip 111. The first chip 111 is between the first thermal conductive element 131 and the substrate 101. The first adhesion layer 121 is disposed on a surface of the first thermal conductive element 131 facing the first chip 111. The first adhesion layer 121 may at least partially cover the surface of the first thermal conductive element 131 facing the first chip 111. The first thermal conductive element 131 may be bonded to the first chip 111 through the first adhesion layer 121. The second thermal conductive element 132 is disposed on the second chip 112. The second chip 112 is between the second thermal conductive element 132 and the substrate 101. The second adhesion layer 122 is disposed on a surface of the second thermal conductive element 132 facing the second chip 112. The second adhesion layer 122 may at least partially cover the surface of the second thermal conductive element 132 facing the second chip 112. The second thermal conductive element 132 may be bonded to the second chip 112 through the second adhesion layer 122. The first adhesion layer 121 may include a first thermal conductive adhesion material. The second adhesion layer 122 may include a second thermal conductive adhesion material. The first thermal conductive adhesion material and the second thermal conductive adhesion material can each independently be a thermally conductive sheet, thermally conductive tape, thermally conductive paste, thermally conductive glue, thermally conductive sealant, etc. The first thermal conductive adhesion material and the second thermal conductive adhesion material can each independently include metal and/or polymer. The first thermal conductive adhesion material of the first adhesion layer 121 and the second thermal conductive adhesion material of the second adhesion layer 122 may be the same as or different from each other. The first thermal conductive element 131 includes a first thermal conductive material having a first thermal conductivity, and the first thermal conductivity includes a first in-plane thermal conductivity and a first cross-plane thermal conductivity. The second thermal conductive element 132 includes a second thermal conductive material having a second thermal conductivity, and the second thermal conductivity includes a second in-plane thermal conductivity and a second cross-plane thermal conductivity. In the present disclosure, the term “cross-plane thermal conductivity” refers to a thermal conductivity along a first direction D1 (or a plane formed by a first direction D1 and a third direction D3) at 273 K, and the term “in-plane thermal conductivity” refers to a thermal conductivity along a second direction D2 (or a plane formed by a second direction D2 and a third direction D3) at 273 K. The first direction D1, the second direction D2 and the third direction D3 are perpendicular to each other. In the present embodiment, the first direction D1 may be a direction of a normal to the upper surface 101U of the substrate 101. The first in-plane thermal conductivity, the first cross-plane thermal conductivity, the second in-plane thermal conductivity and the second cross-plane thermal conductivity may be less than 500. The first in-plane thermal conductivity, the first cross-plane thermal conductivity, the second in-plane thermal conductivity and the second cross-plane thermal conductivity may be greater than 10. The first in-plane thermal conductivity of the first thermal conductive material is less than the first cross-plane thermal conductivity of the first thermal conductive material, that is, the heat conduction rate of the first thermal conductive element 131 along the second direction D2 is less than the heat conduction rate of the first thermal conductive element 131 along the first direction D1. The second in-plane thermal conductivity of the second thermal conductive material is less than the second cross-plane thermal conductivity of the second thermal conductive material, that is, the heat conduction rate of the second thermal conductive element 132 along the second direction D2 is less than the heat conduction rate of the second thermal conductive element 132 along the first direction D1. The first thermal conductive material and the second thermal conductive material may include metal including aluminum, copper, silver, etc. The first thermal conductive material and the second thermal conductive material may be the same as or different from each other. In an embodiment, the first thermal conductive element 131 and the second thermal conductive element 132 include copper or are formed of copper.

One or more first chips 111 are thermally coupled to the first thermal conductive element 131 through the first adhesion layer 121. One or more second chips 112 are thermally coupled to the second thermal conductive element 132 through the second adhesion layer 122. The first adhesion layer 121 may be separated from the second adhesion layer 122. The first thermal conductive element 131 may be separated from the second thermal conductive element 132. There is no physical coupling between the first thermal conductive element 131 and the second thermal conductive element 132. The first thermal conductive element 131 does not directly contact the second thermal conductive element 132. In the present embodiment, air or other gas filled in the module 10 separates the first thermal conductive element 131 and the second thermal conductive element 132, so that there is no direct thermal coupling between the first thermal conductive element 131 and the second thermal conductive element 132; that is, the heat in the first thermal conductive element 131 is not directly transferred to the second thermal conductive element 132 and the heat in the second thermal conductive element 132 is not directly transferred to the first thermal conductive element 131. In the present disclosure, the statement “no direct thermal coupling between two elements” means that the heat transfer between two elements must be achieved through a medium other than the two elements, and the medium may include other elements other than these two elements, gases, etc.

In an embodiment, the heat dissipation device 190 does not include the first adhesion layer 121 and/or the second adhesion layer 122, and the first thermal conductive element 131 and/or the second thermal conductive element 132 can be bonded to the first chip 111 and/or the second chip 112 in other ways.

The thermal conductive layer 141 is disposed on the first thermal conductive element 131 and the second thermal conductive element 132. The first thermal conductive element 131 is between the thermal conductive layer 141 and the substrate 101. The second thermal conductive element 132 is between the thermal conductive layer 141 and the substrate 101. The thermal conductive layer 141 includes a third thermal conductive material having a third thermal conductivity, and the third thermal conductivity includes a third in-plane thermal conductivity and a third cross-plane thermal conductivity. The third in-plane thermal conductivity is greater than the third cross-plane thermal conductivity, that is, the heat conduction rate of the thermal conductive layer 141 along the second direction D2 is greater than the heat conduction rate of the thermal conductive layer 141 along the first direction D1. The third in-plane thermal conductivity may be greater than 1000 or greater than 3000. In an embodiment, the third in-plane thermal conductivity is greater than 3500 and less than 6000. The third in-plane thermal conductivity of the third thermal conductive material may be greater than the first cross-plane thermal conductivity of the first thermal conductive material and greater than the second cross-plane thermal conductivity of the second thermal conductive material. The third thermal conductive material may include graphite material, and the graphite material may include graphite and graphene. In an embodiment, the thermal conductive layer 141 includes graphene or is formed of graphene. The thermal conductive layer 141 may include a multi-layer structure or a single-layer structure. The thermal conductive layer 141 is thermally coupled to the first thermal conductive element 131 and the second thermal conductive element 132. The heat in the first thermal conductive element 131 can be transferred to the thermal conductive layer 141. The heat in the second thermal conductive element 132 can be transferred to the thermal conductive layer 141.

In an embodiment, at least one first chip 111 can control the operating speed of the module 10 according to the operation temperature of each chip in the module 10. For example, when the multi-chip module is in operation, one or more first chips 111 has one or more first operation temperatures, one or more second chips 112 has one or more second operation temperatures, at least one first chip 111 can compare the first operation temperature of each first chip 111 with its first critical operation temperature, and compare the second operation temperature of each second chip 112 with its second critical operation temperature; in response to the comparison result that any first operation temperature is equal to or greater than its first critical operation temperature or any second operation temperature is equal to or greater than its second critical operation temperature, the first chip 111 can cause the module 10 to reduce the operation speed or shut down the module 10, thereby preventing the module 10 from being damaged due to high temperature. The module 10 may further include a temperature sensor for detecting the first operation temperature and the second operation temperature, and the temperature sensor may transmit the measured first operation temperature and second operation temperature to the first chip 111. The temperature sensor may be a separate sensor or may be integrated within the first chip 111.

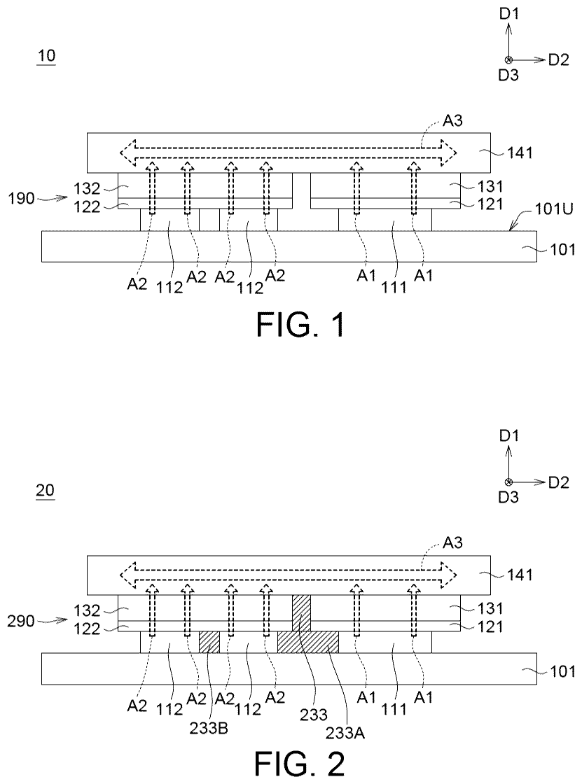

Referring to FIG. 2, FIG. 2 illustrates a schematic view of a module 20 according to an embodiment of the present disclosure. The differences between the module 20 shown in FIG. 2 and the module 10 shown in FIG. 1 are that, besides the elements in the heat dissipation device 190 of the module 10, the heat dissipation device 290 of the module 20 further includes a thermal insulation element 233 and/or a thermal insulation element 233A and/or a thermal insulation element 233B. The thermal insulation element 233 is disposed on the upper surface 101U of the substrate 101. The thermal insulation element 233 is between the first thermal conductive element 131 and the second thermal conductive element 132. The thermal insulation element 233 may be between the first adhesion layer 121 and the second adhesion layer 122. The thermal insulation element 233 may adjoin or directly contact between the first thermal conductive element 131 and the second thermal conductive element 132. The thermal insulation element 233A is disposed on the upper surface 101U of the substrate 101. The thermal insulation element 233A is between the first chip 111 and the second chip 112. The thermal insulation element 233A may adjoin or directly contact between the first chip 111 and the second chip 112. The thermal insulation element 233B is disposed on the upper surface 101U of the substrate 101. The thermal insulation element 233B is between the second chips 112. The thermal insulation element 233B may adjoin or directly contact between the second chips 112. Each of the thermal insulation elements 233, 233A and 233B includes a thermal insulation material having a fourth thermal conductivity, and the fourth thermal conductivity includes a fourth in-plane thermal conductivity and a fourth cross-plane thermal conductivity. The fourth in-plane thermal conductivity and the fourth cross-plane thermal conductivity may be less than 0.2 W/m. K, or less than 0.1 W/m. K. In an embodiment, the fourth in-plane thermal conductivity and the fourth cross-plane thermal conductivity are less than or equal to the thermal conductivity of air. In an embodiment, the thermal conductivity of air can be 0.024 W/m. K, but the present disclosure is not limited thereto. The thermal conductivity of air varies with changes in temperature and pressure. The thermal insulation material may include a porous structure. The thermal insulation material may include glass fiber, rock fiber, asbestos, mineral wool, aerogel, etc. The materials of the thermal insulation elements 233, 233A and 233B may be the same or different. In the present embodiment, the thermal insulation element 233 separates the first thermal conductive element 131 and the second thermal conductive element 132, so that there is no direct thermal coupling between the first thermal conductive element 131 and the second thermal conductive element 132. The thermal insulation element 233 can block heat transfer between the first thermal conductive element 131 and the second thermal conductive element 132. The thermal insulation element 233A can reduce or block heat transfer between the first chip 111 and the second chip 112. The thermal insulation element 233B can reduce or block heat transfer between the second chips 112. The module 20 may include one, two or all of the thermal insulation elements 233, 233A and 233B.

One of the heat dissipation methods which is adapted to the module according to the present disclosure will be exemplarily described below with reference to FIGS. 1 to 2. The heat dissipation method includes: transferring heat in one or more first chips 111 to the first thermal conductive element 131 through the first adhesion layer 121; transferring the heat from the first thermal conductive element 131 to the thermal conductive layer 141. For example, the heat in one or more first chips 111 can be transferred to the first thermal conductive element 131 and the thermal conductive layer 141 along the direction of the arrow A1 shown in FIGS. 1 to 2. The heat dissipation method further includes: transferring heat in one or more second chips 112 to the second thermal conductive element 132 through the second adhesion layer 122; transferring the heat from the second thermal conductive element 132 to the thermal conductive layer 141. For example, the heat in one or more second chips 112 can be transferred to the second thermal conductive element 132 and the thermal conductive layer 141 along the direction of the arrow A2 shown in FIGS. 1 to 2. Since the third in-plane thermal conductivity of the third thermal conductive material of the thermal conductive layer 141 is greater than the third cross-plane thermal conductivity of the third thermal conductive material of the thermal conductive layer 141, heat transferred to the thermal conductive layer 141 (including heat from the first chip 111 and the second chip 112) can be laterally transferred in the thermal conductive layer 141 and distributed in the thermal conductive layer 141. For example, heat in the thermal conductive layer 141 is transferred in the thermal conductive layer 141 along the direction of arrow A3 shown in FIGS. 1 to 2, which can prevent heat from being concentrated in a certain area of the module, causing element damage or affecting the operation efficiency of the module. In the present embodiment, the first chip 111 has a heat conduction path including the first chip 111, the first adhesion layer 121, the first thermal conductive element 131 and the thermal conductive layer 141, and the second chip 112 has a heat conduction path including the second chip 112, the second adhesion layer 122, the second thermal conductive element 132 and the thermal conductive layer 141. The first chip 111 and the second chip 112 have different heat conduction paths.

The heat dissipation method further includes: using air or other gas filled in the module 10 or thermal insulation element 233 of the module 20 to block the first thermal conductive element 131 from directly thermally coupling with the second thermal conductive element 132. Since the heat in the first thermal conductive element 131 is not directly transferred to the second thermal conductive element 132 and the second thermal conductive element 132 is not directly transferred to the first thermal conductive element 131, the heat transfer from the first chip 111 to the second chip 112 and the heat transfer from the second chip 112 to the first chip 111 can be avoided, and the problem of poor heat dissipation efficiency caused by heat transfer between chips can be solved. In an embodiment, the heat dissipation method may include transferring the heat in the thermal conductive layer 141 to the air or other gases filled in the module.

In an embodiment, the heat dissipation method is adapted to the module in operation, at this time, the first chip 111 has a first operation temperature and the second chip 112 has a second operation temperature; the heat dissipation method can include: comparing the first operation temperature of the first chip 111 with the first critical operation temperature of the first chip 111, comparing the second operation temperature of the second chip 112 with the second critical operation temperature of the second chip 112, and reducing the operation speed of the module or turning off the module in response to the comparison result that the first operation temperature is equal to or greater than its first critical operation temperature or the second operation temperature is equal to or greater than its second critical operation temperature.

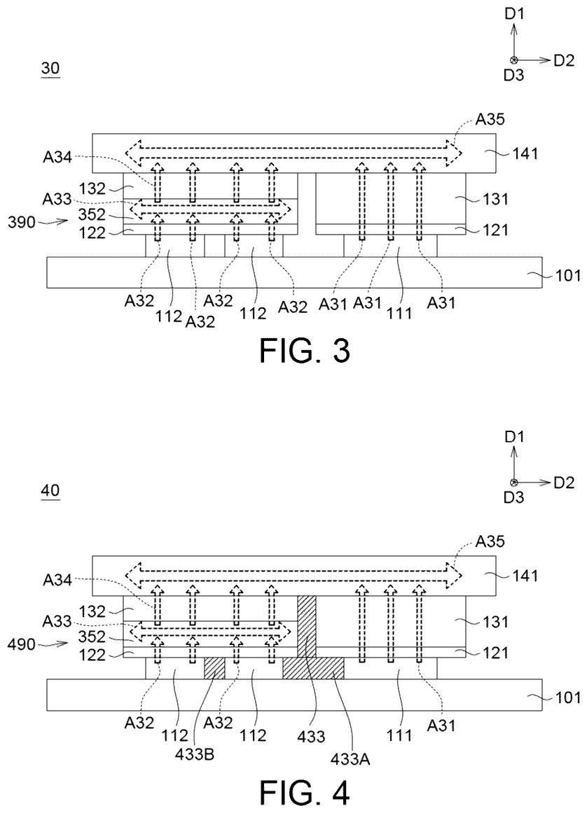

Referring to FIG. 3, FIG. 3 illustrates a schematic view of a module 30 according to an embodiment of the present disclosure. The differences between the module 30 shown in FIG. 3 and the module 10 shown in FIG. 1 are that, besides the elements in the heat dissipation device 190 of the module 10, the heat dissipation device 390 of the module 30 further includes a thermal conductive film 352. The thermal conductive film 352 is disposed between the second chip 112 and the second thermal conductive element 132. The thermal conductive film 352 is disposed between the second adhesion layer 122 and the second thermal conductive element 132. The thermal conductive film 352 is separated from the first thermal conductive element 131. The thermal conductive film 352 includes a fourth thermal conductive material having a fifth thermal conductivity, and the fifth thermal conductivity includes a fifth in-plane thermal conductivity and a fifth cross-plane thermal conductivity. The fifth in-plane thermal conductivity is greater than the fifth cross-plane thermal conductivity, that is, the heat conduction rate of the thermal conductive film 352 along the second direction D2 is greater than the heat conduction rate of the thermal conductive film 352 along the first direction D1. The fifth in-plane thermal conductivity may be greater than 1000 or greater than 3000. In an embodiment, the fifth in-plane thermal conductivity is greater than 3500 and less than 6000. The fifth in-plane thermal conductivity of the fourth thermal conductive material may be greater than the first cross-plane thermal conductivity of the first thermal conductive material and greater than the second cross-plane thermal conductivity of the second thermal conductive material. The fourth thermal conductive material may include graphite material, and the graphite material may include graphite and graphene. In an embodiment, the thermal conductive film 352 includes graphene or is formed of graphene. The thermal conductive film 352 may include a multi-layer structure or a single-layer structure.

The thermal conductive film 352 is thermally coupled to the second thermal conductive element 132 and the second adhesion layer 122. One or more second chips 112 are thermally coupled to the second thermal conductive element 132 through the second adhesion layer 122 and the thermal conductive film 352. In the present embodiment, air or other gas filled in the module 30 separates the first thermal conductive element 131 and the second thermal conductive element 132 and separates the first thermal conductive element 131 and the thermal conductive film 352, and there is no direct thermal coupling between the first thermal conductive element 131 and the second thermal conductive element 132; that is, the heat in the first thermal conductive element 131 is not directly transferred to the second thermal conductive element 132 and the heat in the second thermal conductive element 132 is not directly transferred to the first thermal conductive element 131. Disposing the thermal conductive film 352 on the second chip 112 can accelerate the removal of heat in the second chip 112. In an embodiment in which the module includes multiple second chips 112, using the thermal conductive film 352 can quickly cool down the second chip 112 with a higher operation temperature among the multiple second chips 112.

Referring to FIG. 4, FIG. 4 illustrates a schematic view of a module 40 according to an embodiment of the present disclosure. The differences between the module 40 shown in FIG. 4 and the module 30 shown in FIG. 3 are that, besides the elements in the heat dissipation device 390 of the module 30, the heat dissipation device 490 of the module 40 further includes a thermal insulation element 433 and/or a thermal insulation element 433A and/or a thermal insulation element 433B. The thermal insulation element 433 is between the first thermal conductive element 131 and the second thermal conductive element 132. The thermal insulation element 433 is between the first thermal conductive element 131 and the thermal conductive film 352. The thermal insulation element 433 may be between the first adhesion layer 121 and the second adhesion layer 122. The thermal insulation element 433 may adjoin or directly contact between the first thermal conductive element 131 and the second thermal conductive element 132. The thermal insulation element 433 may adjoin or directly contact between the first thermal conductive element 131 and the thermal conductive film 352. The thermal insulation element 433A is between the first chip 111 and the second chip 112. The thermal insulation element 233A may adjoin or directly contact between the first chip 111 and the second chip 112. The thermal insulation element 433B is between the second chips 112. The thermal insulation element 433B may adjoin or directly contact between the second chips 112. Each of the thermal insulation elements 433, 433A, and 433B includes a thermal insulation material, and the thermal insulation materials of the thermal insulation element 433, 433A, and 433B can be similar to the thermal insulation materials of the thermal insulation elements 233, 233A, and 233B. The materials of the thermal insulation elements 433, 433A and 433B may be the same or different. In the present embodiment, the thermal insulation element 433 separates the first thermal conductive element 131 and the second thermal conductive element 132 and separates the first thermal conductive element 131 and the thermal conductive film 352, so that there is no direct thermal coupling between the first thermal conductive element 131 and the second thermal conductive element 132 and there is no direct thermal coupling between the first thermal conductive element 131 and the thermal conductive film 352. The thermal insulation element 433 can block heat transfer between the first thermal conductive element 131 and the second thermal conductive element 132. The thermal insulation element 433 can block heat transfer between the first thermal conductive element 131 and the thermal conductive film 352. The thermal insulation element 433A can reduce or block heat transfer between the first chip 111 and the second chip 112. The thermal insulation element 433B can reduce or block heat transfer between the second chips 112. The module 40 may include one, two or all of the thermal insulation elements 433, 433A and 433B.

One of the heat dissipation methods which is adapted to the module according to the present disclosure will be exemplarily described below with reference to FIGS. 3 to 4. The heat dissipation method includes: transferring heat in one or more first chips 111 to the first thermal conductive element 131 through the first adhesion layer 121; transferring the heat from the first thermal conductive element 131 to the thermal conductive layer 141. For example, the heat in one or more first chips 111 can be transferred to the first thermal conductive element 131 and the thermal conductive layer 141 along the direction of the arrow A31 shown in FIGS. 3 to 4. The heat dissipation method further includes: transferring heat in one or more second chips 112 to the second thermal conductive element 132 through the second adhesion layer 122 and the thermal conductive film 352; transferring the heat from the second thermal conductive element 132 to the thermal conductive layer 141.

In the present embodiment, transferring heat in one or more second chips 112 to the second thermal conductive element 132 through the second adhesion layer 122 and the thermal conductive film 352 may include the following steps. Transferring heat in one or more second chips 112 to the thermal conductive film 352 through the second adhesion layer 122; for example, the heat in one or more second chips 112 can be transferred to the thermal conductive film 352 along the direction of the arrow A32 shown in FIGS. 3 to 4; since the fifth in-plane thermal conductivity of the fourth thermal conductive material of the thermal conductive film 352 is greater than the fifth cross-plane thermal conductivity of the fourth thermal conductive material of the thermal conductive film 352, heat transferred to the thermal conductive film 352 can be laterally transferred in the thermal conductive film 352 and distributed in the thermal conductive film 352; for example, heat in the thermal conductive film 352 is transferred in the thermal conductive film 352 along the direction of arrow A33 shown in FIGS. 3 to 4, so that the heat in the one or more second chips 112 can be quickly removed. Then, transferring heat in the thermal conductive film 352 to the second thermal conductive element 132; for example, the heat in the thermal conductive film 352 can be transferred to the second thermal conductive element 132 along the direction of the arrow A34 shown in FIGS. 3 to 4. In the present embodiment, the heat in the second thermal conductive element 132 can be transferred to the thermal conductive layer 141 along the direction of the arrow A34 shown in FIGS. 3 to 4.

Since the third in-plane thermal conductivity of the third thermal conductive material of the thermal conductive layer 141 is greater than the third cross-plane thermal conductivity of the third thermal conductive material of the thermal conductive layer 141, heat transferred to the thermal conductive layer 141 (including heat from the first chip 111 and the second chip 112) can be laterally transferred in the thermal conductive layer 141 and distributed in the thermal conductive layer 141. For example, heat in the thermal conductive layer 141 is transferred in the thermal conductive layer 141 along the direction of arrow A35 shown in FIGS. 3 to 4, which can prevent heat from being concentrated in a certain area of the module, causing element damage or affecting the operation efficiency of the module. In the present embodiment, the first chip 111 has a heat conduction path including the first chip 111, the first adhesion layer 121, the first thermal conductive element 131 and the thermal conductive layer 141, and the second chip 112 has a heat conduction path including the second chip 112, the second adhesion layer 122, the thermal conductive film 352, the second thermal conductive element 132 and the thermal conductive layer 141. The first chip 111 and the second chip 112 have different heat conduction paths.

The heat dissipation method further includes: using air or other gases filled in the module 30 or thermal insulation element 433 of the module 40 to block the first thermal conductive element 131 from directly thermally coupling with the second thermal conductive element 132. Since the heat in the first thermal conductive element 131 is not directly transferred to the second thermal conductive element 132 and the second thermal conductive element 132 is not directly transferred to the first thermal conductive element 131, the heat transfer from the first chip 111 to the second chip 112 and the heat transfer from the second chip 112 to the first chip 111 can be avoided, and the problem of poor heat dissipation efficiency caused by heat transfer between chips can be solved. In an embodiment, the heat dissipation method may include transferring the heat in the thermal conductive layer 141 to the air or other gases filled in the module.

In an embodiment, the heat dissipation method is adapted to the module in operation, at this time, the first chip 111 has a first operation temperature and the second chip 112 has a second operation temperature; the heat dissipation method can include: comparing the first operation temperature of the first chip 111 with the first critical operation temperature of the first chip 111, comparing the second operation temperature of the second chip 112 with the second critical operation temperature of the second chip 112, and reducing the operation speed of the module or turning off the module in response to the comparison result that the first operation temperature is equal to or greater than its first critical operation temperature or the second operation temperature is equal to or greater than its second critical operation temperature.

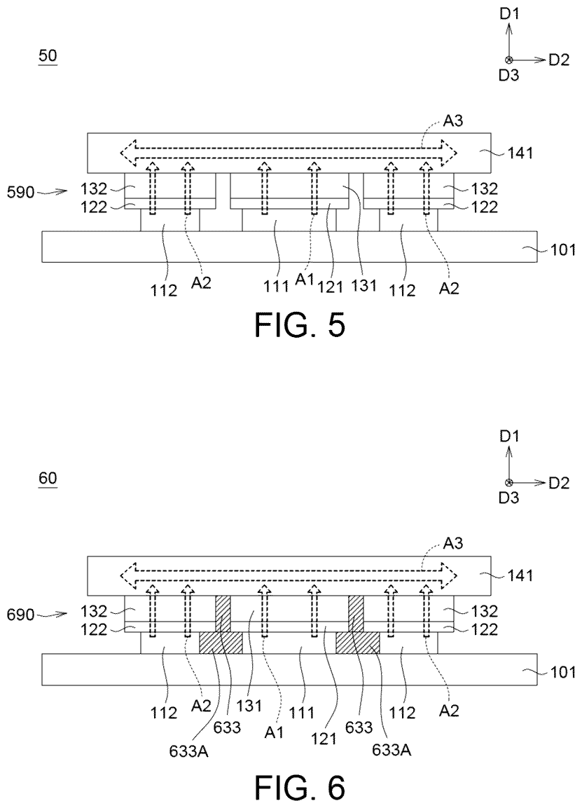

Referring to FIG. 5, FIG. 5 illustrates a schematic view of a module 50 according to an embodiment of the present disclosure. The differences between the module 50 shown in FIG. 5 and the module 10 shown in FIG. 1 are that, the first chip 111 in the module 50 is between the second chips 112, and the heat dissipation device 590 of the module 50 includes a plurality of the second adhesion layers 122 and a plurality of the second thermal conductive elements 132. The heat dissipation device 590 is disposed on one or more first chips 111 and one or more second chips 112. The heat dissipation device 590 includes a first adhesion layer 121, second adhesion layers 122, a first thermal conductive element 131, second thermal conductive elements 132 and a thermal conductive layer 141. The first adhesion layer 121 and the second adhesion layers 122 may be separated from each other. The first thermal conductive element 131 and the second thermal conductive elements 132 may be separated from each other. The first thermal conductive element 131 can be disposed between the second thermal conductive elements 132. Each of the second adhesion layers 122 is disposed on a surface of the second thermal conductive element 132 facing the second chip 112. Each of the second adhesion layers 122 may at least partially cover the surface of the second thermal conductive element 132 facing the second chip 112. Each of the second thermal conductive elements 132 may be bonded to the second chip 112 through the corresponding second adhesion layer 122. The thermal conductive layer 141 is disposed on the first thermal conductive element 131 and the second thermal conductive elements 132. The thermal conductive layer 141 is thermally coupled to the first thermal conductive element 131 and the second thermal conductive elements 132. The heat in the first thermal conductive element 131 can be transferred to the thermal conductive layer 141. The heat in the second thermal conductive elements 132 can be transferred to the thermal conductive layer 141.

There is no physical coupling between the first thermal conductive element 131 and the second thermal conductive elements 132. Each of the second thermal conductive element 132 does not directly contact the first thermal conductive element 131. In the present embodiment, air or other gas filled in the module 50 separates the first thermal conductive element 131 and the second thermal conductive elements 132, so that there is no direct thermal coupling between the first thermal conductive element 131 and the second thermal conductive elements 132; that is, the heat in the first thermal conductive element 131 is not directly transferred to the second thermal conductive elements 132 and the heat in the second thermal conductive elements 132 is not directly transferred to the first thermal conductive element 131.

Referring to FIG. 6, FIG. 6 illustrates a schematic view of a module 60 according to an embodiment of the present disclosure. The differences between the module 60 shown in FIG. 6 and the module 50 shown in FIG. 5 are that, besides the elements in the heat dissipation device 590 of the module 50, the heat dissipation device 690 of the module 60 further includes thermal insulation elements 633 and/or thermal insulation elements 633A. The first thermal conductive element 131 can be between the thermal insulation elements 633. Each of the thermal insulation elements 633 is between the first thermal conductive element 131 and the second thermal conductive element 132. Each of the thermal insulation element 633 may be between the first adhesion layer 121 and the second adhesion layer 122. Each of the thermal insulation elements 633 may adjoin or directly contact between the first thermal conductive element 131 and the second thermal conductive element 132. Each of the thermal insulation elements 633A is between the first chip 111 and the second chip 112. Each of the thermal insulation elements 633A may adjoin or directly contact between the first chip 111 and the second chip 112. Each of the thermal insulation elements 633 and 633A includes a thermal insulation material, and the thermal insulation materials of the thermal insulation element 633 and 633A can be similar to the thermal insulation materials of the thermal insulation elements 233, 233A and 233B. The material of the thermal insulation element 633 may be the same as or different from the material of the thermal insulation element 633A. In the present embodiment, the thermal insulation element 633 separates the first thermal conductive element 131 and the second thermal conductive element 132, so that there is no direct thermal coupling between the first thermal conductive element 131 and the second thermal conductive element 132. The thermal insulation elements 633 can block heat transfer between the first thermal conductive element 131 and the second thermal conductive element 132. The thermal insulation element 633A can reduce or block heat transfer between the first chip 111 and the second chip 112. The module 60 may include the thermal insulation elements 633 and 633A, or may include the thermal insulation elements 633 or 633A.

The heat dissipation methods adapted to the modules 50 and 60 can be similar to the aforementioned heat dissipation methods. In the present embodiment, the first chip 111 has a heat conduction path including the first chip 111, the first adhesion layer 121, the first thermal conductive element 131 and the thermal conductive layer 141, and the second chip 112 has a heat conduction path including the second chip 112, the second adhesion layer 122, the second thermal conductive element 132 and the thermal conductive layer 141. The first chip 111 and the second chip 112 have different heat conduction paths. The second chips 112 may have different heat conduction paths, for example, heat in the second chips 112 may be transferred to the thermal conductive layer 141 through different second adhesion layers 122 and different second thermal conductive elements 132.

FIGS. 5 and 6 show that two second thermal conductive elements 132 on two sides of the first chip 111 each correspond to one second chip 112, but the present disclosure is not limited thereto; each of the second thermal conductive elements 132 may correspond to a plurality of the second chips 112.

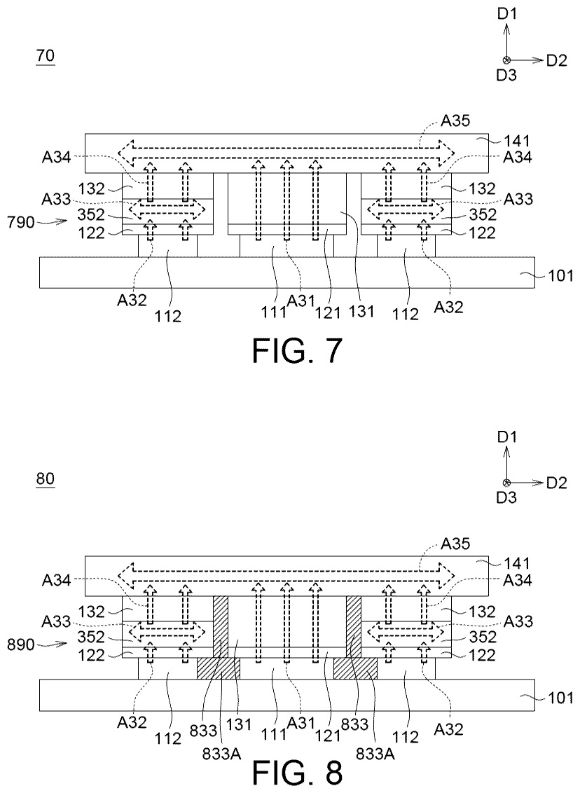

Referring to FIG. 7, FIG. 7 illustrates a schematic view of a module 70 according to an embodiment of the present disclosure. The differences between the module 70 shown in FIG. 7 and the module 30 shown in FIG. 3 are that, the first chip 111 in the module 70 is between the second chips 112, and the heat dissipation device 790 of the module 70 includes a plurality of the second adhesion layers 122, a plurality of the second thermal conductive elements 132 and a plurality of the thermal conductive films 352. The heat dissipation device 790 includes a first adhesion layer 121, second adhesion layers 122, a first thermal conductive element 131, second thermal conductive elements 132, thermal conductive films 352 and a thermal conductive layer 141. The first adhesion layer 121 and the second adhesion layers 122 may be separated from each other. The first thermal conductive element 131 and the second thermal conductive elements 132 may be separated from each other. The thermal conductive films 352 may be separated from each other. The thermal conductive films 352 and the first thermal conductive element 131 may be separated from each other. The first thermal conductive element 131 can be disposed between the second thermal conductive elements 132. The first thermal conductive element 131 can be disposed between the thermal conductive films 352. Each of the thermal conductive films 352 is between the second adhesion layer 122 and the second thermal conductive element 132. Each of the second adhesion layers 122 is disposed on a surface of the thermal conductive film 352 facing the second chip 112. Each of the second adhesion layers 122 may at least partially cover the surface of the thermal conductive film 352 facing the second chip 112. The thermal conductive layer 141 is disposed on the first thermal conductive element 131 and the second thermal conductive elements 132.

Each of the thermal conductive films 352 is thermally coupled to the second thermal conductive element 132 and the second adhesion layer 122. There is no physical coupling between the first thermal conductive element 131 and the second thermal conductive elements 132. Each of the second thermal conductive element 132 does not directly contact the first thermal conductive element 131. In the present embodiment, air or other gas filled in the module 70 separates the first thermal conductive element 131 and the second thermal conductive elements 132 and separates the first thermal conductive element 131 and the thermal conductive film 352, and there is no direct thermal coupling between the first thermal conductive element 131 and the second thermal conductive elements 132; that is, the heat in the first thermal conductive element 131 is not directly transferred to the second thermal conductive elements 132 and the heat in the second thermal conductive elements 132 is not directly transferred to the first thermal conductive element 131. The thermal conductive layer 141 is thermally coupled to the first thermal conductive element 131 and the second thermal conductive elements 132. The heat in the first thermal conductive element 131 can be transferred to the thermal conductive layer 141. The heat in the second thermal conductive elements 132 can be transferred to the thermal conductive layer 141.

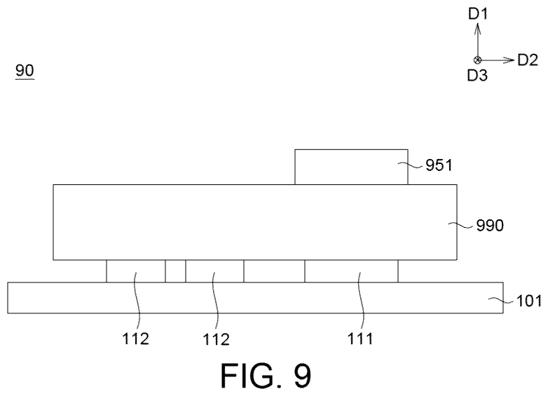

Referring to FIG. 8, FIG. 8 illustrates a schematic view of a module 80 according to an embodiment of the present disclosure. The differences between the module 80 shown in FIG. 8 and the module 70 shown in FIG. 7 are that, besides the elements in the heat dissipation device 790 of the module 70, the heat dissipation device 890 of the module 80 further includes thermal insulation elements 833 and thermal insulation elements 833A. The first thermal conductive element 131 can be between the thermal insulation elements 833. Each of the thermal insulation elements 833 is between the first thermal conductive element 131 and the second thermal conductive element 132. Each of the thermal insulation elements 833 is between the first thermal conductive element 131 and the thermal conductive film 352. Each of the thermal insulation element 833 may be between the first adhesion layer 121 and the second adhesion layer 122. Each of the thermal insulation elements 833 may adjoin or directly contact between the first thermal conductive element 131 and the second thermal conductive element 132. Each of the thermal insulation elements 833 may adjoin or directly contact between the first thermal conductive element 131 and the thermal conductive film 352. Each of the thermal insulation elements 833A is between the first chip 111 and the second chip 112. Each of the thermal insulation elements 833A may adjoin or directly contact between the first chip 111 and the second chip 112. Each of the thermal insulation elements 833 and 833A includes a thermal insulation material, and the thermal insulation materials of the thermal insulation elements 833 and 833A can be similar to the thermal insulation materials of the thermal insulation elements 233, 233A and 233B. The material of the thermal insulation element 833 may be the same as or different from the material of the thermal insulation element 833A. In the present embodiment, the thermal insulation element 833 separates the first thermal conductive element 131 and the second thermal conductive element 132 and separates the first thermal conductive element 131 and the thermal conductive film 352, so that there is no direct thermal coupling between the first thermal conductive element 131 and the second thermal conductive element 132 and there is no direct thermal coupling between the first thermal conductive element 131 and the thermal conductive film 352. The thermal insulation elements 833 can block heat transfer between the first thermal conductive element 131 and the second thermal conductive element 132. The thermal insulation elements 833 can block heat transfer between the first thermal conductive element 131 and the thermal conductive film 352. The thermal insulation element 833A can reduce or block heat transfer between the first chip 111 and the second chip 112. The module 80 may include the thermal insulation elements 833 and 833A, or may include the thermal insulation elements 833 or 833A.

The heat dissipation methods adapted to the modules 70 and 80 can be similar to the aforementioned heat dissipation methods. In the present embodiment, the first chip 111 has a heat conduction path including the first chip 111, the first adhesion layer 121, the first thermal conductive element 131 and the thermal conductive layer 141, and the second chip 112 has a heat conduction path including the second chip 112, the second adhesion layer 122, the thermal conductive film 352, the second thermal conductive element 132 and the thermal conductive layer 141. The first chip 111 and the second chip 112 have different heat conduction paths. The second chips 112 may have different heat conduction paths, for example, heat in the second chips 112 may be transferred to the thermal conductive layer 141 through different second adhesion layers 122, different thermal conductive films 352 and different second thermal conductive elements 132.

Referring to FIG. 9, FIG. 9 illustrates a schematic view of a module 90 according to an embodiment of the present disclosure. The module 90 includes a substrate 101, one or more first chips 111, one or more second chips 112, a heat dissipation device 990 and a fan device 951. The heat dissipation device 990 may be any one of the aforementioned heat dissipation devices 190, 290, 390, 490, 590, 690, 790 and 890 or any combination of the aforementioned heat dissipation devices 190, 290, 390, 490, 590, 690, 790 and 890. The fan device 951 is disposed on the heat dissipation device 990. The heat dissipation device 990 may be between the fan device 951 and the first chip 111. The position of the fan device 951 may correspond to the position of one or more first chips 111. In the first direction D1, the fan device 951 at least partially overlaps one or more first chips 111 (i.e. the projection of the fan device 951 on the substrate 101 at least partially overlaps the projections of one or more first chips 111 on the substrate 101), so that there is a shorter heat conduction path between the fan device 951 and the first chip 111. The fan device 951 can be operated to remove heat. In an embodiment, heat in one or more first chip 111 is transferred to the heat dissipation device 990, and the fan device 951 can be operated to quickly dissipate the heat from the heat dissipation device 990 through active heat dissipation to improve the heat dissipation efficiency of the module. In an embodiment, at least one first chip 111 is a control unit of a solid-state drive, the second chip 112 is a non-volatile storage unit or a volatile storage unit of a solid-state drive; since the operation temperature of the control unit of the solid-state drive is usually higher than that of the storage unit of the solid-state drive, placing the fan device 951 at a position corresponding to one or more first chips 111 can improve the heat dissipation efficiency of the module. The aforementioned heat dissipation methods are also adapted to the module 90.

In a comparative example, a module includes a thermal conductive element covering or thermally coupling all electronic components, and heat in all electronic components is transferred to the thermal conductive element for heat dissipation. Such a design may cause heat in an electronic component with a higher operation temperature to be transferred to an electronic component with a lower operation temperature (e.g., heat in an electronic component with a higher operation temperature is transferred to the thermal conductive element so that the temperature of the thermal conductive element is higher than the operation temperature of another electronic component, and the heat will be transferred from the thermal conductive element to this electronic component with a lower temperature), causing temperature of the electronic component to increase and the module's temperature protection mechanism to be triggered. The temperature protection mechanism will reduce the operation speed of the module or shut down the module to avoid damage to the module due to high temperature. However, frequently triggering the temperature protection mechanism will reduce the performance of the module and may also shorten the service life of the module.

The module including electronic components, such as a module including a solid-state drive, multi-chip module, etc., and the heat dissipation method according to the present disclosure includes thermal conductive elements without direct thermal coupling between these thermal conductive elements and/or thermal conductive elements separated from each other (such as the first thermal conductive element 131 and the second thermal conductive element 132), and the thermal conductive elements can correspond to electronic components having different critical operation temperatures (such as the first chip 111 and the second chip 112), so that the electronic components in the module can dissipate heat through different heat conduction paths. Through such a configuration, the heat in the electronic components will be transferred to the heat dissipation device instead of to other electronic components; therefore, the heat in the electronic components can be quickly dissipated, the heat dissipation effect can be effectively improved, the operating frequency of the temperature protection mechanism of the module can be reduced, and the operation efficiency and service life of the module can be improved. Moreover, in a module comprising a solid-state drive, the operation temperature of the control unit of the solid-state drive is usually much higher than the operation temperatures of other electronic components (such as storage units) of the solid-state drive, the application of the technical content of the present disclosure can effectively remove heat generated by the control unit of the solid-state drive and can improve or prevent the heat generated by the control unit from heating up the storage units. As such, the present disclosure can effectively improve or solve problems such as data errors, data loss, and reduced lifespan of solid-state drive caused by high temperatures. Furthermore, the present disclosure can also be applied to make different storage units in the solid-state drive have different heat conduction paths. For example, the NAND storage unit and the DRAM storage unit in the solid-state drive can have different heat conduction paths.

It is noted that the structures and methods as described above are provided for illustration. The disclosure is not limited to the configurations and procedures disclosed above. Other embodiments with different configurations of known elements can be applicable, and the exemplified structures could be adjusted and changed based on the actual needs of the practical applications. It is, of course, noted that the configurations of figures are depicted only for demonstration, not for limitation. Thus, it is known by people skilled in the art that the related elements and layers in a semiconductor structure, the shapes or positional relationship of the elements and the procedure details could be adjusted or changed according to the actual requirements and/or manufacturing steps of the practical applications.

While the disclosure has been described by way of example and in terms of the exemplary embodiment(s), it is to be understood that the disclosure is not limited thereto. On the contrary, it is intended to cover various modifications and similar arrangements and procedures, and the scope of the appended claims therefore should be accorded the broadest interpretation so as to encompass all such modifications and similar arrangements and procedures.

What is claimed is:

1. A module comprising a solid-state drive, comprising:
a substrate having an upper surface;
a control unit on the upper surface of the substrate and having a first critical operation temperature;
a first storage unit on the upper surface of the substrate and having a second critical operation temperature, wherein the first critical operation temperature is greater than the second critical operation temperature;
a first thermal conductive element on the control unit, wherein the control unit is between the first thermal conductive element and the substrate; and
a second thermal conductive element on the first storage unit, wherein the first storage unit is between the second thermal conductive element and the substrate,
wherein there is no direct thermal coupling between the first thermal conductive element and the second thermal conductive element.

2. The module according to claim 1, further comprising:
a thermal conductive layer on the first thermal conductive element and the second thermal conductive element, wherein the first thermal conductive element is between the thermal conductive layer and the substrate, the second thermal conductive element is between the thermal conductive layer and the substrate, and the thermal conductive layer is thermally coupled to the first thermal conductive element and the second thermal conductive element.

3. The module according to claim 2, wherein the first thermal conductive element or the second thermal conductive element comprises a thermal conductive material having a first thermal conductivity, the thermal conductive layer comprises a thermal conductive material having a second thermal conductivity, and the second thermal conductivity is greater than the first thermal conductivity.

4. The module according to claim 1, wherein the first thermal conductive element or the second thermal conductive element comprises a thermal conductive material having an in-plane thermal conductivity and a cross-plane thermal conductivity, and the in-plane thermal conductivity is less than the cross-plane thermal conductivity.

5. The module according to claim 1, further comprising:
a thermal insulation element on the upper surface of the substrate and between the first thermal conductive element and the second thermal conductive element and/or between the control unit and the first storage unit.

6. The module according to claim 5, wherein the thermal insulation element comprises a thermal insulation material having a thermal conductivity, and the thermal conductivity is less than or equal to the thermal conductivity of air.

7. The module according to claim 1, further comprising:
a second storage unit on the upper surface of the substrate and between the second thermal conductive element and the substrate,
wherein the first storage and the second storage element are thermally coupled to the second thermal conductive element.

8. The module according to claim 7, further comprising:
a thermal conductive film between the first storage unit and the second thermal conductive element and between the second storage unit and the second thermal conductive element, wherein the first storage unit and the second storage unit are thermally coupled to the second thermal conductive element through the thermal conductive film.

9. The module according to claim 8, wherein the second thermal conductive element comprises a thermal conductive material having a first thermal conductivity, the thermal conductive film comprises a thermal conductive material having a second thermal conductivity, and the second thermal conductivity is greater than the first thermal conductivity.

10. The module according to claim 8, further comprising:
a thermal conductive layer on the first thermal conductive element and the second thermal conductive element, wherein the first thermal conductive element is between the thermal conductive layer and the substrate, the second thermal conductive element is between the thermal conductive layer and the substrate, and the thermal conductive layer is thermally coupled to the first thermal conductive element and the second thermal conductive element.

11. The module according to claim 10, wherein the second thermal conductive element comprises a thermal conductive material having a first thermal conductivity, the thermal conductive layer comprises a thermal conductive material having a second thermal conductivity, the thermal conductive film comprises a thermal conductive material having a third thermal conductivity, the second thermal conductivity is greater than the first thermal conductivity, and the third thermal conductivity is greater than the first thermal conductivity.

12. The module according to claim 1, further comprising:
a second storage unit on the upper surface of the substrate, wherein the control unit is between the first storage unit and the second storage unit;
a third thermal conductive element on the second storage unit, wherein the second storage unit is between the third thermal conductive element and the substrate;
a first thermal insulation element on the upper surface of the substrate and between the first thermal conductive element and the second thermal conductive element; and
a second thermal insulation element on the upper surface of the substrate and between the first thermal conductive element and the third thermal conductive element.

13. A multi-chip module, comprising:
a substrate having an upper surface;
a first chip on the upper surface of the substrate and having a first critical operation temperature;
a second chip on the upper surface of the substrate and having a second critical operation temperature, wherein the first critical operation temperature is greater than the second critical operation temperature;
a first thermal conductive element on the first chip, wherein the first chip is between the first thermal conductive element and the substrate; and
a second thermal conductive element on the second chip, wherein the second chip is between the second thermal conductive element and the substrate,
wherein the first thermal conductive element is separated from the second thermal conductive element, the first chip has a first operation temperature and the second chip has a second operation temperature when the multi-chip module is in operation,
in response to the first operation temperature being equal to or greater than the first critical operation temperature or the second operation temperature being equal to or greater than the second critical operation temperature, the first chip reduces the operation speed of the multi-chip module.

14. A heat dissipation method adapted to a multi-chip module, the multi-chip module comprising a control unit having a first critical operation temperature, a first storage unit having a second critical operation temperature less than the first critical operation temperature, a first thermal conductive element, a second thermal conductive element and a thermal conductive layer, wherein the first critical operation temperature is greater than the second critical operation temperature, the heat dissipation method comprising:
transferring heat in the control unit to the first thermal conductive element;
transferring heat in the first storage unit to the second thermal conductive element;
transferring the heat from the first thermal conductive element to the thermal conductive layer;
transferring the heat from the second thermal conductive element to the thermal conductive layer; and
blocking the first thermal conductive element from directly thermally coupling with the second thermal conductive element,
wherein the control unit and the first storage unit have different heat conduction paths.

15. The heat dissipation method according to claim 14, wherein the multi-chip module further comprises a second storage unit, and the heat dissipation method further comprises:
transferring heat in the second storage unit to the second thermal conductive element.

16. The heat dissipation method according to claim 15, wherein the multi-chip module further comprises a thermal conductive film, and the heat dissipation method further comprises:
transferring the heat in the first storage unit to the second thermal conductive element through the thermal conductive film; and
transferring the heat in the second storage unit to the second thermal conductive element through the thermal conductive film.

17. The heat dissipation method according to claim 16, wherein the second thermal conductive element comprises a thermal conductive material having a first thermal conductivity, the thermal conductive layer comprises a thermal conductive material having a second thermal conductivity, the thermal conductive film comprises a thermal conductive material having a third thermal conductivity, the second thermal conductivity is greater than the first thermal conductivity, and the third thermal conductivity is greater than the first thermal conductivity.

18. The heat dissipation method according to claim 14, wherein the multi-chip module further comprises a second storage unit and a third thermal conductive element, the first thermal conductive element, the second thermal conductive element and the third thermal conductive element are separated from each other, and the heat dissipation method further comprises:
transferring heat in the second storage unit to the third thermal conductive element; and
transferring the heat from the third thermal conductive element to the thermal conductive layer.

19. The heat dissipation method according to claim 14, wherein the multi-chip module further comprises a thermal insulation element between the first thermal conductive element and the second thermal conductive element and/or between the control unit and the first storage unit.

20. The heat dissipation method according to claim 14, wherein the first thermal conductive element or the second thermal conductive element comprises a thermal conductive material having a first thermal conductivity, the thermal conductive layer comprises a thermal conductive material having a second thermal conductivity, and the second thermal conductivity is greater than the first thermal conductivity.
